(19) United States
(12) Patent Application Publication
(10) Pub. No.: US 2026/0100683 A1
(43) Pub. Date: Apr. 9, 2026

(54) TRANSMITTER UNIT AND METHOD FOR COUPLING AN ELECTRICAL TRANSMISSION SIGNAL INTO A DC VOLTAGE LINE

(71) Applicant: SMA Solar Technology AG, Niestetal (DE)

(72) Inventors: Dante Bauer, Kassel (DE); Karsten Schnare, Helsa (DE)

(21) Appl. No.: 19/416,513

(22) Filed: Dec. 11, 2025

Related U.S. Application Data
(63) Continuation of application No. PCT/EP2024/068155, filed on Jun. 27, 2024.

(30) Foreign Application Priority Data
Jun. 29, 2023 (DE) 10 2023 117 252.2

(51) Int. Cl. H03F 3/217; H02S 40/32; H03F 1/02

(52) U.S. Cl. CPC H03F 3/2173; H02S 40/32; H03F 1/0233

(57) ABSTRACT

The application relates to a transmitter circuit for coupling a transmission signal into a DC voltage line with two output terminals between which the transmission signal is applied and which are provided for connecting to coupling circuitry in the DC voltage line. The transmitter circuit includes an amplifier circuit with a clocked amplifier, and the amplitude of the transmission signal is proportional to a supply voltage of the clocked amplifier. The transmitter circuit includes a compensation circuit which is configured to detect the amplitude of the transmission signal via a differential voltage measurement at the output terminals and to set the supply voltage of the clocked amplifier depending on the amplitude of the transmission signal. The application also relates to a photovoltaic inverter comprising a transmitter circuit and to a method for coupling a transmission signal into a DC voltage line.

### REFERENCE TO RELATED APPLICATIONS

This application is a Continuation of International Application number PCT/EP2024/068155, filed on Jun. 27, 2024, which claims the benefit of German Application number 10 2023 117 252.2, filed on Jun. 29, 2023. The contents of the above-referenced Patent Applications are hereby incorporated by reference in their entirety.

### FIELD

The application relates to a transmitter circuit for coupling an electrical transmission signal into a DC voltage line and to a photovoltaic inverter having such a transmitter circuit. The application further relates to a method for coupling an electrical transmission signal into a DC voltage line.

### BACKGROUND

Electrical transmission signals can be impressed into, transmitted via and coupled out of DC voltage lines of an electrical installation, for example, in a power generation plant, in particular, for power line communication between different devices connected to the DC voltage lines. In the case of a photovoltaic system, for example, the so-called SunSpec specification of the SunSpec Alliance defines requirements for powerline communication (PLC) between photovoltaic inverters and electronic units on or at the photovoltaic generators. Photovoltaic systems, in particular, therefore regularly include a transmitter circuit in the inverter, which generates a defined electrical transmission signal and couples it into the DC voltage lines.

### SUMMARY

The application is directed to improving such a transmitter unit and such a method for coupling a transmission signal into a DC voltage line.

A transmitter circuit couples an electrical transmission signal into a DC voltage line. Two output connections are provided for the coupling, between which the transmission signal is applied. The output terminals are provided for connection to a coupling circuit in the DC voltage line. The transmitter circuit has an amplifier circuit with a clocked amplifier. The amplitude of the transmitter signal is proportional to a supply voltage of the clocked amplifier, wherein the transmitter circuit comprises a compensation circuit which is configured to detect the amplitude of the transmission signal via a differential voltage measurement at the output terminals and to set the supply voltage of the clocked amplifier depending on the amplitude of the transmission signal.

The electrical transmission signal is thus generated by the transmitter circuit, output via the output terminals, and coupled into the DC voltage line via the coupling circuit. The coupling can in principle be inductive or capacitive, wherein the coupling circuit may, in one embodiment, comprise a coil for inductive coupling. The clocked amplifier of the amplifier circuit can, for example, include a bridge circuit with switches that are controlled in a clocked manner. The compensation circuit can, in one embodiment, comprise an analog circuit part for measuring the differential voltage. The differential voltage measurement has the advantage that the amplitude of the transmission signal can be detected even if the output terminals between which the transmission signal is applied do not have a defined ground reference. Optionally, the compensation circuit can perform a rectification and smoothing of the measurement signal.

A transmitter circuit according to the disclosure makes it possible to automatically set the transmission signal to a desired amplitude value and to compensate for any deviations from this, which may be caused, for example, by component tolerances, changes in the ambient conditions, or changes in the DC circuits connected to the DC lines. This improves the quality of the electrical transmission signal and thus the data transmission, without requiring manual intervention in the transmitter circuit, e.g., after installation of the transmitter circuit or the inverter or after changes to the photovoltaic system.

In an advanced embodiment of the transmitter circuit, in order to set the supply voltage of the clocked amplifier, the compensation circuit is configured to output a compensation signal depending on the amplitude of the transmission signal. Using such a compensation signal depending on the amplitude of the transmission signal, the real amplitude of the transmission signal at the output terminals can be taken into account when setting the supply voltage of the clocked amplifier, even if the supply voltage is generated separately, i.e. not by the compensation circuit itself but by a separate voltage supply. The transmitter circuit is in turn configured so that the amplitude of the transmission signal is proportional to the supply voltage of the clocked amplifier, such that the amplitude can be set to the desired value by the described design of the compensation circuit.

In one embodiment of the transmitter circuit, a nominal DC supply voltage is provided, wherein the supply voltage of the clocked amplifier is adjustable depending on the nominal DC supply voltage and on the compensation signal in a range between half the nominal DC supply voltage of a voltage supply and twice this nominal DC supply voltage. The nominal DC supply voltage can, for example, be a nominal output voltage of a voltage supply of the clocked amplifier, which can be manipulated by the compensation signal. Depending on the compensation signal, the supply voltage of the clocked amplifier and thus the amplitude of the transmission signal can then be changed in the range between half and twice a nominal value. This allows feedback of the real amplitude of the transmission signal to be realized in order to ensure a transmission signal with sufficient amplitude. In one embodiment, the supply voltage of the clocked amplifier can be set in a range from approximately 4 volts to approximately 10 volts.

In one embodiment, the transmitter circuit comprises a DC/DC converter which is configured to generate the supply voltage of the clocked amplifier from a higher-level system voltage depending on the amplitude of the transmission signal or depending on the compensation signal. The DC/DC converter can receive either the amplitude of the transmission signal or a value dependent thereon from the compensation circuit in order to generate the supply voltage. Alternatively, the DC/DC converter can receive the compensation signal from the compensation circuit to generate or scale the supply voltage. The compensation signal can here be either analog or digital.

In one embodiment, the transmitter circuit comprises a processor circuit configured to generate the compensation signal in digital form as a clock sequence with a duty cycle and to transmit it to the compensation circuit, wherein the duty cycle is set by the processor circuit depending on the amplitude of the transmission signal. This embodiment has the advantage that the digital signal processing can be carried out in the processor circuit separately from the compensation circuit, which can be designed or configured as an analog circuit.

In one embodiment of the transmitter circuit, the compensation circuit outputs the clock sequence as a compensation signal in digital form as a control signal for semiconductor switches of the DC/DC converter. In this embodiment, the compensation circuit can directly control the semiconductor switches of the DC/DC converter, which allows a fast response of the DC/DC converter and thus a fast control of the generation of the supply voltage. The controlling of the semiconductor switches of the DC/DC converter can be carried out alternatively or in addition to the controlling of the semiconductor switches by a control unit of the DC/DC converter.

In one embodiment of the transmitter circuit, the compensation circuit comprises a filter which generates the compensation signal from the clock sequence as a voltage level in analog form and outputs it to a control input of the DC/DC converter. In this embodiment, the analog compensation signal acts as a control signal on the generation of the supply voltage, for example, by scaling a nominal output voltage of the DC/DC converter using the analog compensation signal.

In one embodiment of the transmitter circuit, the transmission signal can be coupled into two transmission channels. The transmitter unit can be switched between the two transmission channels. The supply voltage of the clocked amplifier or the compensation signal can be switched, depending on the transmission channel, in alternating fashion between a first and a second supply voltage or between a first and a second compensation signal. This embodiment enables two-channel operation of the transmitter unit, in which the amplitude of the transmission signal for each channel can be well regulated independently of the other channel.

In one embodiment of the transmitter circuit, the compensation circuit has a temperature sensor for temperature detection. The supply voltage of the clocked amplifier or the compensation signal here depends on the detected temperature. This makes it possible to compensate for temperature dependencies, which further improves the quality of the transmission signal.

In one embodiment of the transmitter circuit, the amplifier circuit is configured to generate a modulation of the transmission signal depending on a binary setting signal. The amplifier circuit can thus convert a binary reference signal into a modulated transmission signal which can then be coupled into the DC voltage line. For this purpose, the binary reference signal can be generated from a desired continuous signal form, for example, using pulse width modulation or delta-sigma modulation. The transmission signal can, for example, be frequency-modulated with a fixed, predetermined amplitude and can have multiple, for example, two, alternatively used frequencies.

In one embodiment, the clocked amplifier can comprise a half-bridge circuit with semiconductor switches which are controlled in a clocked manner. The gain of the amplifier circuit here depends directly on the supply voltage, and the transmission signal is generated by suitable clocking of the semiconductor switches of the half-bridge.

In one embodiment of the transmitter circuit, the amplifier circuit comprises a class D amplifier circuit. The class D amplifier circuit comprises a class D amplifier. A class D amplifier is a switching amplifier that can be used as a power amplifier. The class D amplifier works in switching mode to amplify a binary signal. Semiconductor power switches, e.g. transistors, in the bridge circuit of the class D amplifier are here operated in two discrete states, either conducting or isolating. As a result, the class D amplifier has little power loss.

A photovoltaic inverter comprises the transmitter circuit according to one embodiment of the disclosure. The transmitter circuit is designed or configured to couple the transmission signal into the DC voltage lines of the DC bus. The DC bus connects the inverter to at least one photovoltaic generator for electrical power exchange. The disclosed transmitter circuit enables the inverter to communicate via the DC bus with receivers connected thereto. In addition, components that are already installed in the inverter can optionally be used for the controlling of the amplitude of the transmission signal by the transmitter circuit. This means that the additional effort required to influence the amplitude of the transmission signal can be kept to a minimum. For example, the internal system voltage of the inverter can be used to generate the supply voltage for the amplifier circuit. In addition, a DC/DC converter provided in the inverter can be used to generate the supply voltage for the amplifier circuit from the internal system voltage. This reduces the cost and complexity of the transmitter unit and/or of the inverter.

In one embodiment, a photovoltaic system can comprise the disclosed inverter. The photovoltaic system can also comprise at least one photovoltaic generator and the DC bus. The DC bus connects the inverter to the photovoltaic generator for the electrical power transfer. The transmitter circuit then enables data communication between the inverter and the receivers assigned to the photovoltaic generator.

In a method for coupling a transmission signal into a DC voltage line, the transmission signal is applied between two output terminals which are connected to a coupling means in the DC voltage line. An amplifier circuit with a clocked amplifier generates the transmission signal with an amplitude proportional to a supply voltage of the clocked amplifier. A compensation circuit detects the amplitude of the transmission signal via a differential voltage measurement at the output terminals and sets the supply voltage of the clocked amplifier accordingly.

### BRIEF DESCRIPTION OF THE FIGURES

The disclosure is further explained and described below with reference to exemplary embodiments illustrated in the figures.

FIG. 1 schematically shows a first example embodiment of a transmitter circuit.

FIG. 2 schematically shows a second example embodiment of a transmitter circuit.

FIG. 3 schematically shows an example embodiment of a photovoltaic system.

FIG. 4 schematically shows a method for coupling in a transmission signal.

FIG. 5 schematically illustrates a two-channel operation.

FIG. 6 schematically shows a method for setting the voltage for the two-channel operation.

The same reference signs are used in the figures for identical or similar elements. The representations in the figures may not be to scale.

### DETAILED DESCRIPTION

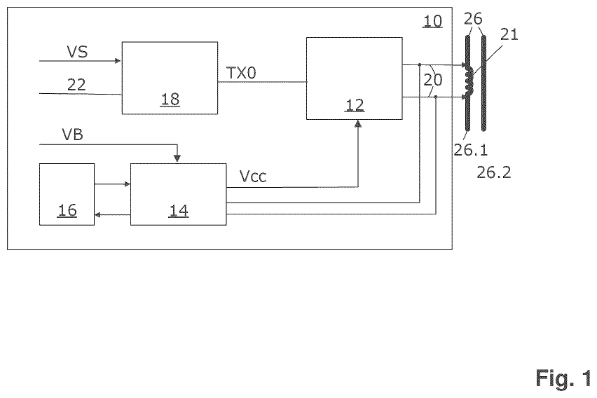

FIG. 1 shows a first example embodiment of a transmitter circuit 10. The transmitter circuit 10 is connected to a DC bus 26 via output terminals 20. The DC bus 26 has two DC voltage lines 26.1, 26.2. The output terminals 20 of the transmitter circuit 10 are connected to the one DC voltage line 26.1 of the DC bus 26. An electrical transmission signal present between the output terminals 20 can be coupled to the DC voltage line 26.1 via a coupling circuit 21, e.g. an inductance. The transmitter circuit 10 is used to transmit information encoded in the transmission signal via the DC bus 26 using powerline communication. The transmitter circuit 10 can, for example, be a powerline transmitter that is basically compatible with the SunSpec standard and/or similar relevant standards for communication, for example, in a photovoltaic system.

An amplifier circuit 12 of the transmitter circuit 10 has, in one embodiment, a clocked amplifier, which can, for example, have a half-bridge with semiconductor switches. The amplification of the amplifier circuit 12 is achieved, in one embodiment, by a suitable clocked switching of a supply voltage Vcc using the semiconductor switches, for example. The amplifier circuit 12 thus amplifies a binary reference signal TX0 and generates an electrical transmission signal which is then applied between the output terminals 20. The amplifier circuit 12 is designed or configured such that an amplitude of the transmission signal is proportional to a supply voltage Vcc of the clocked amplifier and can, for example, comprise a class D amplifier for this purpose.

A signal generator circuit 18 is supplied by a signal generator supply voltage VS. The signal generator circuit 18 outputs the binary reference signal TX0 which can be generated by a coding from, in one embodiment, an inherently continuously predetermined signal curve. For example, the predetermined signal curve can qualitatively correspond to the curve of the desired transmission signal. Suitable codings for the desired transmission signal or the continuous signal curve include, for example, delta-sigma modulation or pulse width modulation. An input signal 22 can be stored in the signal generator 18, e.g., via a programming interface in a flash memory. In one embodiment, the input signal 22 can be identical to the binary reference signal TX0, which is continuously output as a transmission signal, for example, for the single-channel transmitter circuit 10 shown in FIG. 1.

In one embodiment, the reference signal TX0 is derived from a continuous signal which has, e.g., a desired signal curve with various fixed frequencies, each with a fixed amplitude. By suitable clocking and filtering, the amplifier circuit 12 translates the reference signal TX0 from the coded binary form back into an analog electrical transmission signal which is applied to the coupling circuit 21. The amplitude of the transmission signal at the coupling circuit 21 is on the one hand proportional to the supply voltage Vcc of the clocked amplifier circuit 12, and can on the other hand exhibit scatter due to tolerances of components of the amplifier circuit 12 and variations depending on ambient conditions or on the DC units connected to the DC bus 26. Accurate detection, control and setting of the amplitude of the transmission signal is therefore beneficial for the quality of data transmission via the DC bus.

Any scattering or undesired variation in the amplitude of the transmission signal can thereby be compensated for in accordance with the application. The scattering can occur, for example, due to component tolerances, and a variation in the amplitude of the transmission signal can occur, for example, due to aging of ceramic capacitors and/or due to temperature-related dependencies and/or depending on electrical parameters of a connected PV generator 36 (not shown in FIG. 1).

The transmitter circuit 10 has a compensation circuit 14, which is supplied with electrical power from an internal system voltage VB and supplies the clocked amplifier circuit 12 with the supply voltage Vcc. Optionally, the supply voltage Vcc of the clocked amplifier circuit 12 can be generated by the compensation circuit 14 itself from the internal system voltage VB.

The compensation circuit 14 also detects the electrical transmission signal at the output terminals 20 via a differential voltage measurement. The compensation circuit 14 is designed or configured to set the supply voltage Vcc of the clocked amplifier circuit 12 depending on the amplitude of the transmission signal. This has the advantage that the actual real amplitude of the transmission signal can be detected at the output terminals 20 and the supply voltage Vcc of the clocked amplifier circuit 12 can be set accordingly to adapt the amplitude to the setpoint value.

The detection of the amplitude of the transmission signal and the setting of the supply voltage Vcc of the clocked amplifier circuit 12 can be carried out, in one embodiment, by an analog circuit arrangement of the compensation circuit 14.

Optionally, an item of information derived from the detected amplitude of the transmission signal can be transferred to a processor circuit 16 via the compensation circuit 14. Depending on this information, the processor circuit 16 can generate a digital compensation signal which can be transmitted, for example, as a clock sequence with a duty cycle, from the processor circuit 16 to the compensation circuit 14. The duty cycle of the digital compensation signal can be set by the processor circuit 16 depending on the amplitude of the transmission signal, e.g. by means of a proportional controller and/or an integrating proportional controller, in each case optionally with a characteristic curve. The supply voltage Vcc of the clocked amplifier circuit 12 can then be set by the compensation circuit 14 depending on the digital compensation signal received from the processor 16, for example, by clocked switching of the internal system voltage VB according to the clock sequence of the digital compensation signal received from the processor circuit 16. In a basic embodiment, the compensation circuit 14 can comprise, in addition to the differential voltage detection, the analog signal processing by filters or the like of the measured signals heading to the processor circuit 16 and of the clocked compensation signal coming from the processor circuit 16.

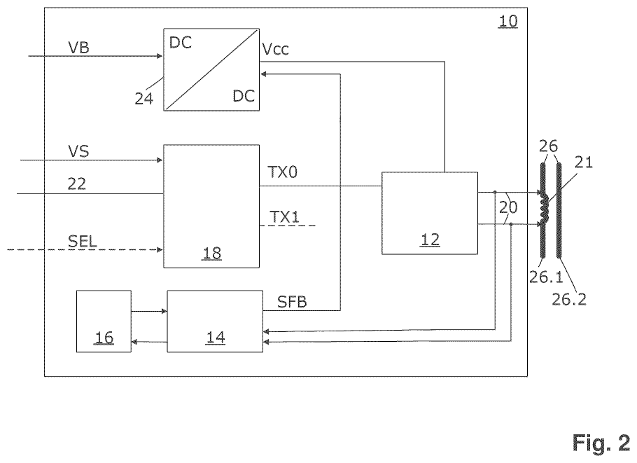

FIG. 2 illustrates a further example embodiment of the transmitter circuit 10. Differing from FIG. 1, the transmitter circuit 10 in this example embodiment comprises a DC/DC converter 24. The DC/DC converter 24 is designed or configured, for example, as a clocked device and has controllable semiconductor switches. The DC/DC converter 24 generates the supply voltage Vcc for the amplifier circuit 12 from the internal system voltage VB depending on a compensation signal SFB received from the compensation circuit 14. In this example embodiment, the compensation circuit 14 itself can also be supplied with electrical energy from the internal system voltage VB.

The compensation circuit 14 generates the compensation signal SFB depending on the amplitude of the transmission signal. The amplitude of the transmission signal can be detected in an analogous manner as in the transmitter unit 10 of FIG. 1. The measured amplitude or an item of information proportional thereto can be forwarded to a processor circuit 16, which, depending on this information, can generate a digital compensation signal by means of a control and/or by using a characteristic curve, and return it to the compensation circuit 14.

In this example embodiment, the compensation circuit 14 can output a compensation signal SFB which, in digital form, is suitable as a control signal for semiconductor switches of the DC/DC converter 24. The compensation circuit 14 can then, for example, directly control the semiconductor switches of the DC/DC converter 24, for example, if the digital compensation signal generated by the processor circuit 16 is used, directly or after suitable filtering, as the compensation signal SFB.

The compensation circuit 14 can also comprise a filter which generates a voltage level in analog form from the digital compensation signal received from the processor circuit 16, and outputs this voltage level as a compensation signal SFB to a control input of the DC/DC converter. The compensation signal SFB can then directly determine the supply voltage Vcc to be output by the DC/DC converter 24 or can modify a nominal DC supply voltage of the DC/DC converter 24, i.e. effect a scaling of the supply voltage Vcc. Alternatively, it would be possible to use the compensation signal SFB directly, i.e. instead of the internal system voltage VB, as the supply voltage of the DC/DC converter 24 (not shown here).

The transmitter circuit 10 is designed or configured for two-channel transmission, so that the transmitter circuit 10 can be switched between at least two transmitting channels, wherein in each case the transmission signal, via the at least two transmitting channels, can be coupled into different DC buses. The currently used channel can here be selected via a channel selection signal SEL. The signal generator 18 can output in alternating fashion two binary reference signals TX0, TX1, wherein the first reference signal TX0 is output to the output terminals 20 via the amplifier circuit 12 at a supply voltage Vcc with a first value, while the second setting signal TX1 is output via a second amplifier circuit (not shown) to the output terminals thereof and coupled into a second DC bus at a supply voltage Vcc with a second value different from the first value (not shown). The input signal 22 can here be identical to the respective binary reference signal TX0, TX1, which can be output continuously in alternating fashion. The compensation signal SFB can be switched in alternating fashion between a first and a second compensation signal SFB depending on the transmission channel, wherein the first compensation signal SFB is generated depending on the amplitude of the transmission signal at the coupling circuit 21 and the second compensation signal SFB is generated depending on the amplitude of the transmission signal at a further coupling means (not shown) in a DC voltage line of the second DC bus (not shown here). This makes it possible to use some components, at least the compensation circuit 14, a processor circuit 16, the signal generator circuit 18 and the DC/DC converter 24 in multiple ways to generate PLC signals on different DC buses with possibly differing assignment of DC units.

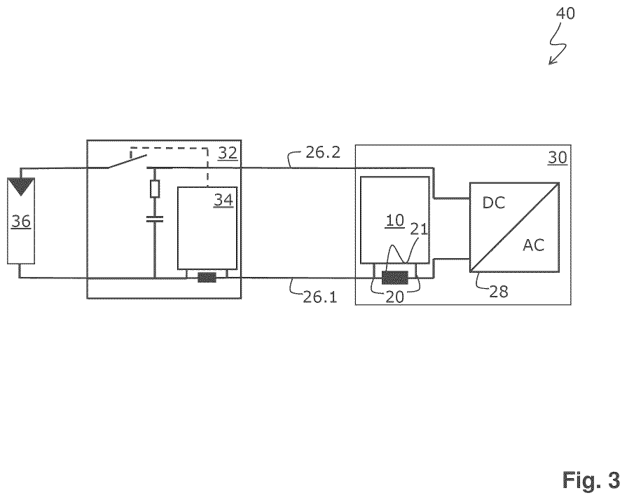

FIG. 3 schematically shows a photovoltaic system 40 with an inverter 30, a DC bus with the DC voltage lines 26.1 and 26.2, a PV generator 36, and a disconnector 32. In the case of multiple PV generators 36, which can be connected in series to the one DC bus or in parallel via multiple DC buses to the inverter 30, one disconnector 32 can be provided per DC bus or per PV generator 36.

The inverter 30 comprises an inverter bridge circuit 28 and at least one coupling circuit 21 per connected DC bus. The coupling circuit 21 is provided to couple the transmission signal applied between the output terminals 20 of the transmitter circuit 10 into a DC voltage line 26.1 of the DC bus 26.

The disconnector switch 32 is an example of a receiver for the transmission signal and comprises a receiving circuit 34 which is configured to receive the transmission signal transmitted by the transmitter circuit 10. Depending on the received transmission signal, the disconnector 21 can disconnect the PV generator 36 from the inverter 30, for example, by opening an electronic DC switch, or connect it to the inverter 30 by closing the electronic DC switch.

Such a disconnector 32 comprising the receiver circuit 34 for communication via the DC bus can be used, for example, to implement a single-fault-protected switch-on and switch-off device for PV generators. An advantage of communication via the DC bus 26 is that no additional cabling or radio interfaces need to be installed. The transmission signal for communication via the DC bus is generated and coupled as described, e.g. by the transmitter circuit 10 in the inverter, wherein sufficient signal quality of the transmission signal is ensured by the compensation circuit according to the application.

In order to ensure single-fault protection of the PV system 40, a specific signal can be sent by the transmitter circuit 10, for example, every second during normal operation of the PV system 40. The disconnector 32 evaluates the signal received via the receiver circuit 34 and switches the DC voltage of the PV generator 36 through to the DC bus when the correct bit stream is detected. If for example the DC bus 26 is interrupted or the inverter 30 is defective or the PV system 40 is switched off for other reasons so that the signal no longer reaches the PV generator 36, the disconnector 32 can automatically switch off the PV generator 36. This means that the entire PV system 40 can be reliably disconnected from the power supply if necessary.

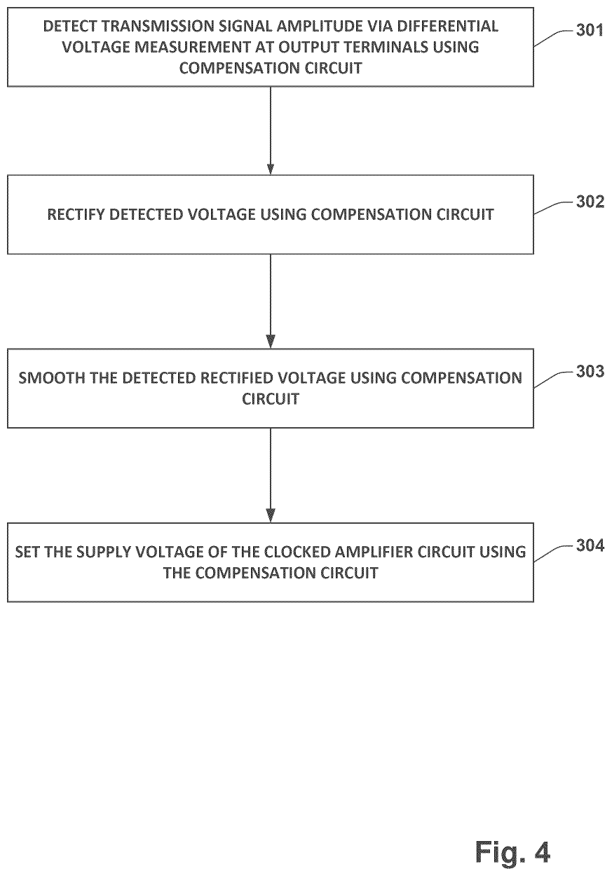

FIG. 4 schematically shows a method for coupling the transmission signal into the DC voltage line 26.1. The transmission signal is applied between the two output terminals 20, which are connected to the coupling circuit 21 in the DC voltage line 26.1.

In 301, the compensation circuit 14 detects the amplitude of the transmission signal via a differential voltage measurement at the output terminals 20, which are connected to the coupling circuit 21. In 302, the compensation circuit 14 rectifies the detected voltage of the transmission signal, e.g. by means of a diode. In 303, the compensation circuit 14 smooths the detected rectified voltage. The smoothing can be done, for example, by a type of peak value formation by integrating the rectified voltage. In 304, the compensation circuit 14 sets the supply voltage Vcc of the clocked amplifier. The setting in 304 can be done, for example, by direct setting of the supply voltage Vcc by the compensation circuit 14 (see FIG. 1) or by outputting the compensation signal SFB to a DC/DC converter 24 (see FIG. 2).

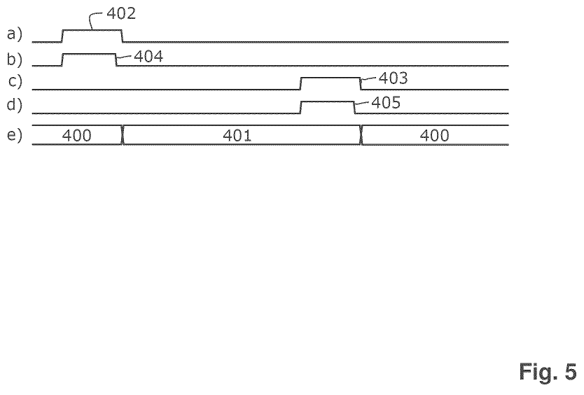

FIG. 5 schematically illustrates a two-channel operation. In FIG. 5e), 400 designates those time periods for a first channel in which the supply voltage Vcc for the clocked amplifier circuit connected to a first DC bus is optimized by feedback of the amplitude of the transmission signal on this first DC bus, and 401 designates those time periods for a second channel in which the supply voltage Vcc for the clocked amplifier circuit connected to a second DC bus is optimized by feedback of the amplitude of the transmission signal on this first DC bus. In FIG. 5a), 402 denotes the time period in which the transmission signal of the first channel is active, while, largely at the same time, in time period 404 the control of the supply voltage Vcc is active depending on the measured amplitude of the transmission signal on the first channel. After switching the supply voltage Vcc to the second channel, at 403 the activity of the second channel begins, and accordingly during 405 the controlling of the supply voltage Vcc depending on the measured amplitude of the transmission signal on the second channel takes place. FIGS. 5a) to 5e) show that the channels each transmit during the transmission pause of the other channel. The controlling of the supply voltage Vcc is started in advance before the activity of the transmission signal of the respective channel.

The implementation of two-channel operation is possible through the alternating mode of operation in one embodiment. Two independent control processes are defined in the software for this purpose. Predictive voltage switching allows seamless switching between the channels.

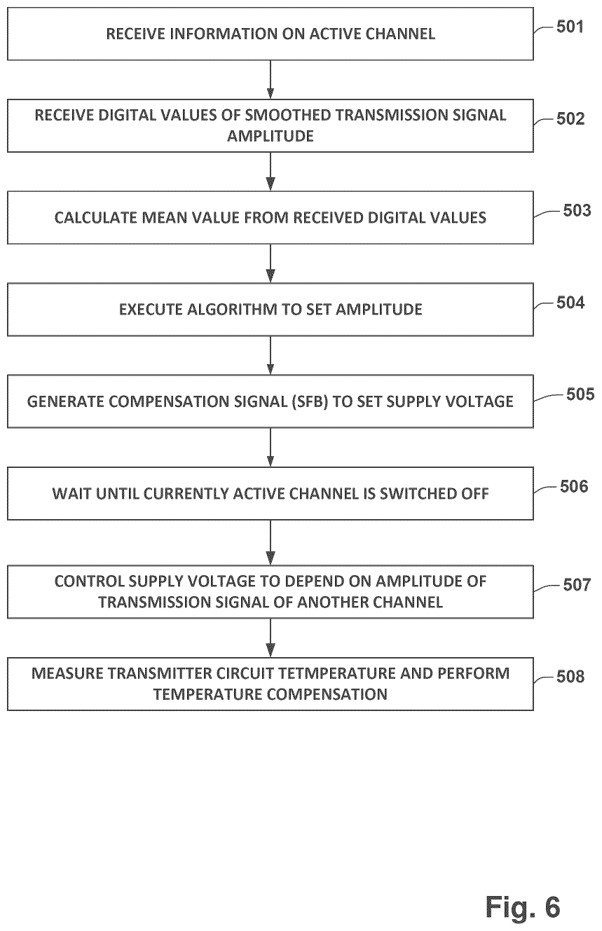

FIG. 6 shows a schematic diagram of a voltage setting method for two-channel operation. The method according to FIG. 6 can run, for example, in the processor 16. In 501, the information as to which channel is active is received. In 502, the digitized values of the smoothed amplitude of the transmission signal of the active channel are received. In 503, the mean value is formed from the values received in 502 for interference suppression. In 504, the control algorithm for amplitude setting is carried out. In 505, the compensation signal SFB is generated, e.g. in the form of a duty cycle or an analog voltage level, and used to set the supply voltage Vcc. In 506, the system waits until the currently active channel is switched off, and in 507 the controlling of the supply voltage Vcc is switched to depend on the amplitude of the transmission signal of the other channel. In 508, the temperature of the transmitter unit 10 is optionally measured in order to be able to perform an optional additional temperature compensation.

By using active controlling, the amplitude of the transmission signal can be kept close to the required amplitude with very narrow tolerance. Deviations that arise e.g. due to component tolerances can be reliably compensated for. By using the averaged measured value in the controlling, the entire output signal can be used as the controlled variable, instead of the individual oscillation of the amplitude as controlled variable. This makes the control system robust against disturbances, such as harmonics from the inverter 30.

What is claimed is:

1. A transmitter circuit for coupling an electrical transmission signal into a DC voltage line, comprising two output terminals between which the electrical transmission signal is applied and which are configured to connect to a coupling circuit in the DC voltage line, wherein the transmitter circuit comprises an amplifier circuit comprising a clocked amplifier, and wherein an amplitude of the electrical transmission signal is proportional to a supply voltage of the clocked amplifier,
wherein the transmitter circuit comprises a compensation circuit which is configured to detect the amplitude of the transmission signal via a differential voltage measurement at the two output terminals and to set the supply voltage of the clocked amplifier depending on the amplitude of the transmission signal.

2. The transmitter circuit according to claim 1, wherein the compensation circuit is configured to output a compensation signal depending on the amplitude of the transmission signal in order to set the supply voltage of the clocked amplifier.

3. The transmitter circuit according to claim 2, wherein a nominal DC supply voltage is provided to the transmitter circuit, wherein the supply voltage of the clocked amplifier is adjustable in a range between half the nominal DC supply voltage and twice the nominal DC supply voltage depending on the nominal DC supply voltage and on the compensation signal.

4. The transmitter circuit according to claim 3, wherein the supply voltage of the clocked amplifier is adjustable in a range from approximately 4 volts to approximately 10 volts.

5. The transmitter circuit according to claim 2, further comprising a DC/DC converter which is configured to generate the supply voltage of the clocked amplifier from a higher-level system voltage depending on the amplitude of the transmission signal or depending on the compensation signal.

6. The transmitter circuit according to claim 2, wherein the compensation signal output by the compensation circuit is analog or digital.

7. The transmitter circuit according to claim 2, further comprising a DC/DC converter which is configured to generate the supply voltage of the clocked amplifier from a higher-level system voltage depending on the amplitude of the transmission signal or depending on the compensation signal, wherein the transmitter circuit comprises a processor circuit which is configured to generate a digital compensation signal as a clock sequence with a duty cycle and to transmit the digital compensation signal to the compensation circuit, wherein the duty cycle of the digital compensation signal is set by the processor circuit depending on the amplitude of the transmission signal.

8. The transmitter circuit according to claim 7, wherein the compensation circuit receives the clock sequence, and passes the clock sequence to its output, wherein the compensation circuit outputs the clock sequence as the compensation signal in digital form as a control signal for semiconductor switches of the DC/DC converter.

9. The transmitter circuit according to claim 7, wherein the compensation circuit comprises a filter which receives the compensation signal as the clock sequence and modifies the compensation signal from the clock sequence to an analog compensation signal having a voltage level in analog form and outputs the analog compensation signal to a control input of the DC/DC converter.

10. The transmitter circuit according to claim 1, wherein the transmission signal is coupled into two transmission channels, wherein the transmitter circuit is switched between the two transmission channels, and wherein the supply voltage of the clocked amplifier or the compensation signal is switched in alternating fashion between a first supply voltage and a second supply voltage or between a first compensation signal and a second compensation signal depending on the transmission channel.

11. The transmitter circuit according to claim 1, wherein the compensation circuit comprises a temperature sensor for temperature detection and wherein the supply voltage of the clocked amplifier or the compensation signal depends on a temperature detected by the temperature sensor.

12. The transmitter circuit according to claim 1, wherein the amplifier circuit is configured to generate a modulation of the transmission signal depending on a binary setting signal.

13. The transmitter circuit according to claim 1, wherein the clocked amplifier comprises a half-bridge circuit with semiconductor power switches.

14. The transmitter circuit according to claim 1, wherein the amplifier circuit comprises a class D amplifier circuit.

15. A photovoltaic inverter comprising a transmitter circuit for coupling an electrical transmission signal into a DC voltage line, the transmitter circuit comprising two output terminals between which the electrical transmission signal is applied and which are configured to connect to a coupling circuit in the DC voltage line, wherein the transmitter circuit comprises an amplifier circuit comprising a clocked amplifier, and wherein an amplitude of the transmission signal is proportional to a supply voltage of the clocked amplifier,
wherein the transmitter circuit comprises a compensation circuit which is configured to detect the amplitude of the transmission signal via a differential voltage measurement at the two output terminals and to set the supply voltage of the clocked amplifier depending on the amplitude of the transmission signal, and
wherein the transmitter circuit is configured to couple the electrical transmitter signal into the DC voltage line, wherein a DC bus comprises the DC voltage line, and the DC bus connects the photovoltaic inverter to at least one photovoltaic generator for electrical power exchange.

16. A photovoltaic system comprising a photovoltaic inverter, the at least one photovoltaic generator, and the DC bus according to claim 15, configured to provide electrical power transfer.

17. A method for coupling a transmission signal into a DC voltage line, wherein the transmission signal is applied between two output terminals which are connected to a coupling circuit in the DC voltage line, comprising:
generating the transmission signal using an amplifier circuit with a clocked amplifier, wherein the transmission signal comprises an amplitude that is proportional to a supply voltage of the clocked amplifier,
detecting the amplitude of the transmission signal via a differential voltage measurement at the output terminals using a compensation circuit, and
setting the supply voltage of the clocked amplifier based on the detected transmission signal amplitude using the compensation circuit.
